(19) United States
(12) Patent Application Publication
(10) Pub. No.: US 2026/0101558 A1
(43) Pub. Date: Apr. 9, 2026

(54) METHOD FOR PRODUCING STRUCTURED METAL CONTACTS ON A SEMICONDUCTOR SUBSTRATE

(71) Applicant: Fraunhofer-Gesellschaft zur Föerderung der angewandten Forschung e.V., Muenchen (DE)

(72) Inventors: Carsten HELLINGER, Erlangen (DE); Michael THUM, Erlangen (DE)

(21) Appl. No.: 19/316,060

(22) Filed: Sep. 2, 2025

(30) Foreign Application Priority Data
Sep. 2, 2024 (DE) 10 2024 124 978.1

(51) Int. Cl. H10D 64/01; H10P 14/40; H10P 34/42

(52) U.S. Cl. CPC H10D 64/01125; H10P 14/418; H10P 34/42

(57) ABSTRACT

In a method for producing structured metallic contacts on a semiconductor substrate, in one embodiment a layer sequence consisting of multiple metallic contact materials is deposited on the entire surface of the semiconductor substrate, and a further metallic contact material is applied on the layer sequence in predetermined contact regions. Then, the layer sequence in the contact regions undergoes a thermal treatment to form a low impedance contact from a Schottky contact. The thermal treatment is carried out by scanning the layer sequence with a laser beam. In the method, the wavelength of the laser beam, the metallic contact material of the topmost layer of the layer sequence and the further metallic contact material are tuned to each other in such a way that the metallic contact material of the topmost layer of the layer sequence has a reflectivity for the laser beam that is 1.3 times higher than that of the further metallic contact material. This results in a self-adjusting thermal treatment without the need for an additional protective mask.

### TECHNICAL FIELD

The present invention relates to a method for producing structured metal contacts on a semiconductor substrate, in which a layer of one or a layer sequence of several metallic contact materials, from which the contacts are at least partially made, is deposited on the semiconductor substrate, structured, and then undergoes thermal treatment, in which the one or more contact materials is/are alloyed into the semiconductor substrate to form a low impedance contact from a Schottky contact between the one or more metallic contact materials and the semiconductor substrate.

The formation of contacts with the lowest possible resistance is necessary for the manufacture of semiconductor devices with low forward resistance. In vertical components, on 4H—SiC wafers, for example, the structured metallic contacts on the wafer front side consist as standard of nickel-containing metallisations (e.g., NiAl (2.6 wt. %) or pure nickel) for n-type contacts, and titanium-aluminium based metallisations for p-type contacts. The total-or full surface rear side contacts also typically consist of nickel-containing metallisations. Since the deposited metal only forms Schottky contacts on many substrate materials, in particular on 4H—SiC as well, the metallisation must undergo thermal treatment.

### PRIOR ART

Thermal treatment entails a RTP step (RTP: Rapid Thermal Processing) as standard, in which the wafer is heated up to about 1000° C. for 2 minutes, for example, which causes the metal contacts to alloy.

For the purpose of treating the full surface rear side contact, in addition to this technique in recent years laser processing with UV short pulse lasers has also gained popularity. In this process, the entire surface of the rear side of the wafer is scanned with the laser. This generates very high local temperatures, and this also alloys the contact. This method produces contacts with the same low impedances as RTP. But this laser processing is not suitable for alloying structured front side contacts, because in this process the layers between the contacts are damaged by the laser radiation, rendering the components unusable.

From US 2023/0155000 A1, a method is known for producing structured metal contacts on a semiconductor substrate, in which, before the metal contacts are alloyed, a mask reflecting the laser radiation is deposited on the semiconductor substrate and structured in such a way that it only has openings on the contacts that are to be alloyed. The contacts are then alloyed into the substrate by laser processing through these openings.

The problem addressed by the present invention consists in specifying a method for producing structured metal contacts on a semiconductor substrate that does not require a RTP step and enables formation of low impedance contacts with high geometric precision in a short time.

### PRESENTATION OF THE INVENTION

The problem is solved with the method according to Claim 1. Advantageous variants of the method are the subject matter of the dependent claims or may be discerned from the following description and the exemplary embodiment.

In the suggested method, a layer of a metallic contact material, or a layer sequence of several metallic contact materials, from which the contacts are at least partially formed, is deposited on the total or full surface of the semiconductor substrate. A further metallic contact material is then applied to this layer or layer sequence in predetermined contact regions, which determine the geometry of the subsequent metallic contacts. This is done preferably by depositing and structuring a photoresist layer on the layer or layer sequence in a first step, so that the photoresist layer has passable openings on the predetermined contact regions. The further metallic contact material is then deposited over the entire surface in a second step, in such manner that the openings are at least partially filled with this material. Then, in a third step, the photoresist layer is removed again, for example using a lift-off process, so that the further metallic contact material is only applied to the predetermined contact regions on the layer or layer sequence. In principle, however, other techniques may also be used to apply the further metallic contact material locally to the layer or layer sequence in the predetermined contact regions.

Since the contact materials of the layer or layer sequence in the suggested method form a Schottky contact with the underlying semiconductor substrate, a thermal treatment is required in which the one or more contact materials are alloyed into the semiconductor substrate in the predetermined contact regions in order to create a low impedance (ohmic) contact from the Schottky contact. In the suggested method, this is done by scanning the layer or layer sequence containing the locally applied further metallic contact material with a laser beam. The present method is characterized in that the metallic contact material of the layer (in the case of just a single layer) or the topmost layer of the layer sequence, the further metallic contact material and the laser wavelength of the laser beam used are tuned to each other in such manner that the metallic contact material of the layer or the topmost layer of the layer sequence has at least 1.3 times, preferably at least 1.5 times greater reflectivity for the laser beam than the further metallic contact material. As a result, the laser beam is reflected significantly more effectively in the region between the predetermined contact regions and therefore does not heat these regions as intensively as in the predetermined contact regions. When the laser power is chosen appropriately, at least the metallic contact material that is in contact with the substrate or all of them in the predetermined contact regions is/are alloyed into the semiconductor substrate, whereas the temperature required for this is not reached in the intermediate regions. The metallic contact material of the layer or the topmost layer of the layer sequence is preferably selected such that it has a reflectivity R of ≥80 % for the laser beam. The material of the layer or layer sequence that is not alloyed in between the predetermined contact regions is subsequently removed again. This removal of the layer or layer sequence between the predetermined contact regions can be carried out in known manner using wet chemical techniques. But other known removal techniques are also possible.

The suggested method can also be used to produce structured low impedance metallic contacts, in particular front side contacts in semiconductor manufacturing, with high geometrical precision without RTP. In contrast, targeted, purely local laser processing for alloying the contact materials would entail significant disadvantages, as the adjustment of the semiconductor substrate would have to be in the micrometre range and the laser beam would have to be guided with high precision, whereby the diameter of the laser beam is not universally suitable for all contact sizes due to its size. The suggested method is also applicable regardless of contact geometry and can be used not only for rectangular but also for round contacts, for example. Compared with the application of an additional protective mask in the intermediate regions, such as a hard oxide mask, again the suggested method can be implemented in a shorter process duration.

In the proposed method, the layer or layer sequence is preferably scanned with the laser over its full or total surface. In principle, scanning might also be done only in regions where the predetermined contact regions are located, since the geometry of the contacts is not determined by the laser, but rather by the further metallic contact material applied.

For the purposes of the present, the term “structured contacts” is understood to mean geometrically defined contact regions that are separated from each other. The term “full or total surface deposition or scanning” means covering or scanning the entire substrate or layer surface without any remaining gaps. The term contact material is used simply to indicate that it is a material used to establish the contact and is therefore part of that contact.

For the thermal treatment, it is preferable to use a laser beam with a wavelength in the UV range, for example at a wavelength of λ=355 nm. The layer sequence preferably consists of one layer of titanium, and one layer of aluminium forming the topmost layer of the layer sequence. Additional intermediate layers are also possible. Aluminium has a reflectivity R of ≈92 % at the wavelength of 355 nm. For this layer sequence, titanium or nickel, which have a reflectivity R of ≈55 % (titanium) and ≈59 % (nickel) at the wavelength of 355 nm are preferably used as further metallic contact material. Aluminium thus has a reflectivity for the laser beam that is about 1.67 times greater than titanium and a reflectivity for the laser beam about 1.56 times greater than nickel. The semiconductor substrate may be made for example from 4H—SiC, in which the metallic contacts are alloyed by silicidation. Either a cw laser or a pulsed laser may be used as the laser. The wavelength is also not limited to the UV range defined earlier.

The method can be used in all areas of semiconductor manufacturing in which low impedance metallic contacts are to be created on a semiconductor substrate, which without thermal treatment would only form Schottky contacts between the metallic contact material and the semiconductor substrate. The suggested method may be applied particularly advantageously to produce structured p-type contacts on a 4H—SiC semiconductor substrate.

### BRIEF DESCRIPTION OF THE DRAWING

In the following text, the suggested method will be explained again, in greater detail, with reference to an exemplary embodiment in conjunction with the drawing. In the drawing:

FIG. 1A-1G is a schematic representation of various steps in an exemplary production of p-type contacts on a 4H—SiC semiconductor substrate according to the invention.

### WAYS TO IMPLEMENT THE INVENTION

In the suggested method, a self-adjusting process is used to alloy structured metallic contacts into a semiconductor substrate. In this process, the reflectivity of the metal layers used for the contacts with regard to the laser type used is exploited. Laser wavelength and metallic contact materials or metals are suitably matched for this purpose.

In the present exemplary embodiment, structured p-type contacts are produced on a 4H—SiC wafer. In this case, the metals or contact materials titanium and aluminium used as standard for such p-type contacts are used for the metallisations or layers. Titanium and aluminium have very different reflectivities in the UV range at λ=355nm, as was noted earlier.

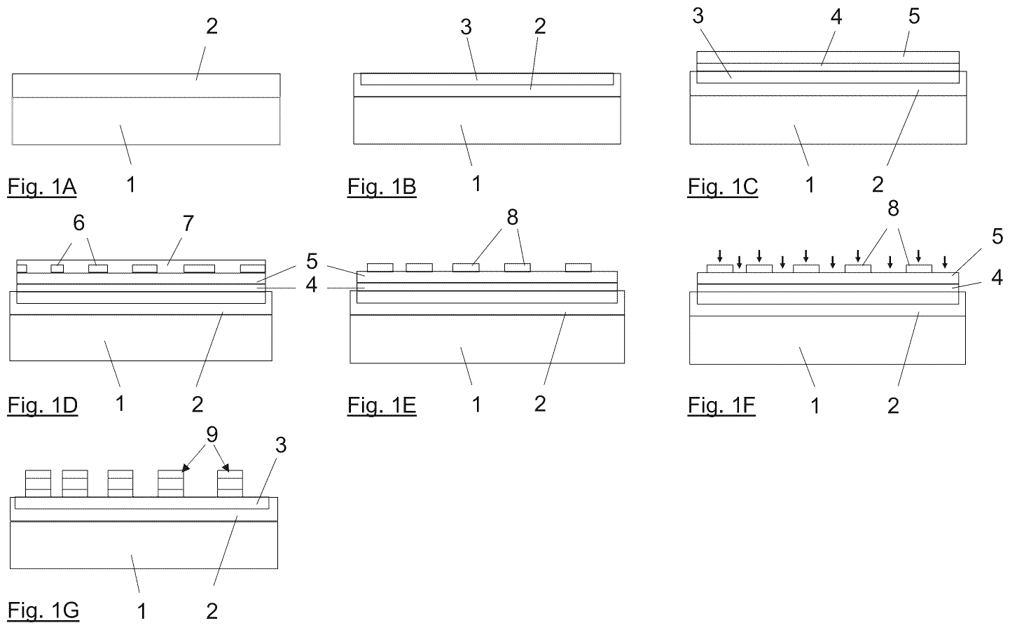

In the process explained in this example with reference to FIG. 1, in the first step, according to FIG. 1A, an epitaxial n-type layer (7-9×10¹⁵ cm⁻³) is first grown on the n-type 4H—SiC wafer 1. In the second step, according to FIG. 1B, a p₊ implantation of Al is made in the epitaxial layer 2, forming the p⁺ implantation layer 3. In the next step, the contact metal stack consisting of a bottom layer 4 of titanium 4 and a top layer 5 of aluminium is then deposited.

This standard titanium-aluminium metallisation is deposited on the entire surface of the wafer front side, as shown in FIG. 1C. Following this, a photoresist layer is applied on top of this layer sequence and structured in such a way that the openings created define the geometries of the predetermined contact regions. Then, a layer 7 of titanium (as further metallic contact material) is applied by vapour deposition to this photoresist layer 6. FIG. 1D shows the structured photoresist layer 6 with titanium layer 7 applied, which layer (here) completely fills the openings in the photoresist layer. The photoresist is then removed in a lift-off process, leaving structured titanium contacts 8 on the full-surface titanium-aluminium layer sequence 4, 5 (FIG. 1E). Then, the entire area of the wafer surface, or the surface of the layer sequences applied, is processed with the laser, as indicated by the arrows in FIG. 1F. The laser radiation is coupled in at the sites where the titanium layer 7 is topmost, and the titanium-aluminium-titanium stack reacts with the SiC substrate (alloying). At the sites between the predetermined contact regions, where the aluminium layer 5 is topmost, most of the laser radiation is reflected and consequently a chemical reaction does not take place with the SiC substrate.

After the laser processing, the aluminium layer 5 and the titanium layer 4 between the predetermined contact regions are removed with wet chemical processes. The titanium layer 4 can be removed with a dilute mixture of HNO₃ and HF, for example, the aluminium layer 5 can be removed with a dilute mixture of H₃PO₄, HNO₃ and HAc, for example. The silicided titanium-aluminium-titanium stack then remains as the structured p-type contact 9 to be produced, as illustrated in FIG. 1G.

In the example above, only metallic contact materials that have been used previously as standard to produce the p-type contacts on 4H—SiC are used. Thus, in this example the method advantageously does not introduce any additional materials into the process but merely changes the stacking sequence of the metallisations.

### LIST OF REFERENCE NUMERALS

1 n-type 4H—SiC Wafer
2 n-type epitaxial layer
3 p⁺ implantation layer
4 Titanium layer
5 Aluminium layer
6 Structured photoresist layer
7 Titanium layer
8 Structured titanium contacts
9 Structured p-type contact

1. Method for producing structured metallic contacts
(9) on a semiconductor substrate (1, 2), in which
a layer consisting of one or a layer sequence (4, 5) consisting of multiple metallic contact materials, by which the contacts (9) are at least partially formed, is deposited on the full surface of the semiconductor substrate (1, 2),
a further metallic contact material (7) is deposited on the layer or layer sequence (4, 5) consisting of the one or more metallic contact materials in predetermined contact regions, by which a geometry of the metallic contacts (9) is defined,
the layer or layer sequence (4, 5) then undergoes a thermal treatment, in which the one or more contact materials is/are alloyed into the semiconductor substrate (1, 2) in the predetermined contact regions, to form a low impedance contact from a Schottky contact between the one or more metallic contact materials and the semiconductor substrate (1, 2), and
the layer or layer sequence (4, 5) is then removed again between the predetermined contact regions,
wherein the thermal treatment is carried out by scanning the layer or layer sequence (4, 5) with a laser beam, and the metallic contact material of the layer or of a topmost layer of the layer sequence (4, 5), the further metallic contact material (7) and a laser wavelength of the laser beam are tuned to each other in such a way that the metallic contact material of the layer or of the topmost layer of the layer sequence (4, 5) has a reflectivity for the laser beam that is at least 3 times higher than that of the further metallic contact material (7).

2. Method according to claim 1,
characterized in that
the metallic contact material of the layer or of the topmost layer of the layer sequence (4, 5) has a reflectivity R of ≥80 % for the laser beam.

3. Method according to claim 1,
characterized in that
a laser beam with a wavelength in the UV range, in particular with a wavelength of 355 nm is used for the thermal treatment.

4. Method according to claim 1,
characterized in that
the layer sequence (4, 5) is formed from a layer of titanium (4) and a layer of aluminium (5), wherein the layer of aluminium (5) is the topmost layer of the layer sequence (4, 5).

5. Method according to claim 4,
characterized in that
titanium or nickel is used as the further metallic contact material (7).

6. Method according to claim 1,
characterized in that
the semiconductor substrate (1, 2) is a 4H—SiC semiconductor substrate.

7. Method according to claim 1 for producing structured p-type contacts on a 4H—SiC semiconductor substrate.

8. Method according to claim 1,
characterized in that
after the layer or layer sequence (4, 5) of the one or more metallic contact materials is deposited, a photoresist layer is applied on top of the layer or layer sequence (4, 5), and is structured to enable the further metallic contact material (7) to be applied on the layer or layer sequence (4, 5) subsequently only in the predetermined contact regions, wherein the photoresist layer is subsequently removed again using a lift-off process.

9. Method according to claim 1,
characterized in that
the layer or layer sequence (4, 5) between the predetermined contact regions is removed with wet chemical processes.
